(19) United States
(12) Patent Application Publication
(10) Pub. No.: US 2012/0060896 A1
(43) Pub. Date: Mar. 15, 2012

(54) Device and method for cooling solar cells by means of a flowing cooling medium

(76) Inventor: Jochen Schäfer, Nurnberg (DE)

(21) Appl. No.: 13/321,920

(22) PCT Filed: May 20, 2010
(86) PCT No.: PCT/EP2010/056961

§ 371 Date: Nov. 22, 2011

(30) Foreign Application Priority Data
May 26, 2009 (DE) 10 2009 022 671.0

(51) Int. Cl. H01L 31/052; H01L 31/024

(52) U.S. Cl. 136/246; 136/259

(57) ABSTRACT

A device for cooling solar cells by a flowing cooling medium is provided. The cooling medium is in direct or indirect thermal contact with at least one solar cell and with an external cooling unit. The cooling medium at least partially includes a phase transition material. Further, a method for cooling solar cells is provided.

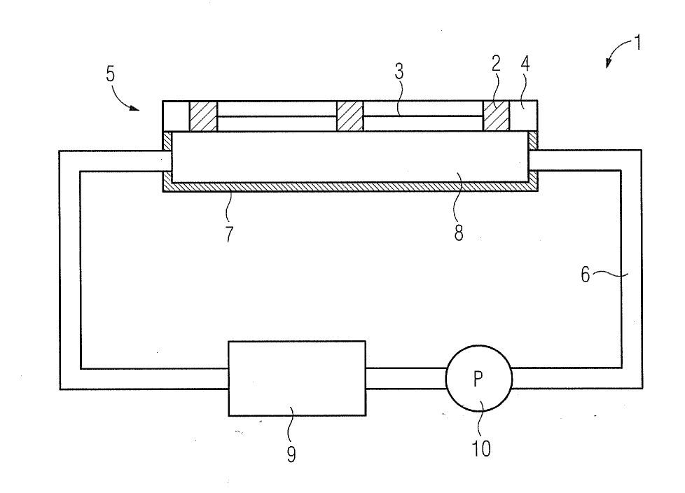

### CROSS REFERENCE TO RELATED APPLICATIONS

This application is the US National Stage of International Application No. PCT/EP2010/056961 filed May 20, 2010, and claims the benefit thereof. The International Application claims the benefits of German Application No. 10 2009 022 671.0 DE filed May 26, 2009. All of the applications are incorporated by reference herein in their entirety.

### FIELD OF INVENTION

The present invention relates to a device and a method for cooling solar cells by means of a flowing cooling medium, wherein the cooling medium is in direct or indirect thermal contact with at least one solar cell and an external cooling unit.

### BACKGROUND OF INVENTION

The efficiency of solar or photovoltaic cells, in particular solar cells based on silicon (Si), is dependent inter alia on the temperature. As the temperature rises, the degree of efficiency decreases by approximately 0.4 percent per degree Celsius in the case of crystalline Si solar cells, and in the case of amorphous Si solar cells the degree of efficiency decreases by approximately 0.1 percent per degree Celsius. Under direct solar irradiation the temperature of a solar cell increases significantly above the ambient temperature, e.g. by over 35 degrees Celsius. This results in a calculated loss in efficiency of about 14 percent in the case of crystalline Si solar cells and a loss in efficiency of about 3.5 percent in the case of amorphous Si solar cells.

When considering efficiency levels, e.g. 5 to 7 percent in the case of commercially produced amorphous Si solar cells and 16 to 20 percent in the case of commercially produced crystalline Si solar cells, it quickly becomes clear that the operating temperature of a solar cell constitutes an important factor in terms of its yield. Reducing the temperature can lead to a significant increase in the performance of the solar cells at the same level of light irradiation. In general a reduction in temperature is achieved by means of an installation of the solar cells in which an air flow is made possible or forced and a corresponding solar cell module is cooled by means of air. Alternatively active cooling circuits, e.g. based on water cooling, can also be provided.

An example of active cooling of solar cells with the aid of a cooling circuit is known from DE 20 2007 002 087 U1. Described in DE-U1 is a system in which a cooling liquid flows over the rear side of a solar cell and absorbs heat from the solar cell in the process. The cooling liquid flows through a tube of a cooling circuit to a cooling unit, e.g. a water tank, where the cooling liquid releases the absorbed heat again. The cooled cooling liquid then flows via a tube to the rear side of the solar cell, where the circuit is closed and the cooling process is repeated.

Both in the case of a solar installation using air cooling and in the case of cooling with the aid of a cooling liquid such as e.g. water, the low thermal capacity of the medium used for cooling can lead to problems. Under strong solar irradiation during the operation of the solar installation, a large quantity of waste heat is produced at the solar cells which must be removed in an effective manner in order to increase efficiency. As a result of the low thermal capacity of air and liquids such as e.g. water, not all of the accumulating waste heat of the solar cells can be absorbed and conveyed away. A high flow velocity of the cooling medium and consequently a high level of technical complexity are suitable only to a limited degree for removing the high quantity of heat and cooling the solar cells effectively. Moreover, a high flow velocity is associated with a high energy requirement in order to generate the flow.

### SUMMARY OF INVENTION

An object of the present invention is to disclose a device and a method for cooling solar cells in which effective cooling is ensured with comparatively little technical complexity and low energy consumption. In particular, it is an object to disclose a device and a method in which a high thermal capacity of the cooling medium leads to an effective removal of the heat accumulating at the solar cells under solar irradiation. In this way it is aimed, with a simple structure, to guarantee low-cost, effective cooling of the solar cells, thereby achieving a high level of efficiency of the solar cells.

The addressed object is achieved by a device for cooling solar cells by means of a flowing cooling medium and by a method as claimed in the independent claims.

Advantageous embodiments of the device and of the method for cooling solar cells by means of a flowing cooling medium will be apparent from the respectively associated dependent claims. At the same time the features of the coordinated claims, can be combined with features of a respectively associated dependent claim or preferably also with features of several associated dependent claims.

The device for cooling at least one solar cell has a flowing cooling medium. The device is cooled by means of the flowing cooling medium, the cooling medium being in direct or indirect thermal contact with the at least one solar cell and with an external cooling unit. The cooling medium includes a phase transition material or consists of said phase transition material. In the present context a phase transition material shall be understood to mean a material in which a phase transition is utilized or takes place during the operation of the device. What is preferably to be understood by phase transition is the phase transition from the liquid to the solid phase and vice versa. However, the phase transition can also be understood to mean a phase transition from the liquid to the gaseous phase and vice versa as well as a phase transition from the solid to the gaseous phase and vice versa.

The use of a cooling medium which includes a phase transition material results in a high thermal capacity of the cooling medium, because a very great quantity of heat can be stored during the phase transition of the phase transition material. During the flowing of the cooling medium a high quantity of heat can be conveyed from the at least one solar cell to the external cooling unit by means of the phase transition material. A higher heat flow rate is thus achieved at the same flow velocity of the cooling medium compared with a cooling medium consisting for example of pure water. A reliable cooling of the at least one solar cell is made possible in this way over a long time and at high ambient temperatures or when a large quantity of heat is supplied to the at least one solar cell through light irradiation.

In an embodiment variant of the device, the cooling medium consists of a cooling fluid and the phase transition material. The cooling fluid enables a flow to be maintained even during a solid phase of the phase transition material.

The phase transition material can include paraffin or salt, in particular sodium acetate trihydrate, as at least one component or consist entirely of said component. These materials have a high thermal capacity.

The phase transition material can have a phase change temperature in the range between +20 and +70 degrees Celsius. In this temperature range the cooling unit is still able to release heat stored in the phase transition material to the environment of the cooling unit at ambient temperatures below the phase change temperature. Furthermore a temperature of the solar cells without solar irradiation lies in or below this range. Cooling of the solar cells under solar irradiation leads to an increase in efficiency. Cooling down of the solar cells under solar irradiation to or close to a temperature of the solar cells without solar irradiation leads to an optimum level of efficiency.

The higher the specific thermal capacity of the phase transition material, the more heat can be conveyed from the solar cells to the cooling unit at the same flow velocity of the cooling medium. Cooling of the solar cells is improved and the degree of efficiency increased. The phase transition material should have a specific thermal capacity of greater than two kilojoules (per kilogram per kelvin) in order to achieve effective cooling of the solar cells.

The phase transition material can be incorporated in a closed loop or circuit. With the aid of the cooling medium the rear side of the at least one solar cell can be thermally coupled by way of the circuit to a heat accumulator and/or to the cooling unit and/or to a heat exchanger. If the cooling medium is transparent, it is also possible to cool the solar cells from the front side.

The circuit can be closed and in the circuit there can be disposed a pump which is embodied to allow the cooling medium to flow from the rear side of the at least one solar cell to the heat accumulator and/or to the cooling unit and to allow the cooling medium to flow back from the heat accumulator and/or from the cooling unit to the rear side of the solar cell in the closed circuit. Embodying the circuit as a closed loop prevents the loss of cooling medium, i.e. the cooling medium consists at least in part of the phase transition material.

In a method for cooling solar cells by means of a flowing cooling medium, at least one solar cell is brought into direct or indirect thermal contact with the cooling medium. A phase transition material is incorporated within the cooling medium.

A mixture composed of the phase transition material and a cooling fluid can be used as the flowing cooling medium. During the cooling of the at least one solar cell the cooling fluid in this case flows in the liquid state at all times and the phase transition material is conveyed in all its phases, in particular in the liquid and the solid phase, in the cooling fluid as the cooling fluid flows. This stops the phase transition material from blocking the cooling circuit in the solid phase and preventing the cooling medium from flowing. A blocked cooling circuit will prevent or impede the cooling of the at least one solar cell.

Paraffin or a salt, in particular sodium acetate trihydrate, or salt mixtures can be used as the phase transition material. In the solid phase the phase transition material can be present in the cooling fluid substantially as a colloid.

Water or an oil or an oil mixture can be used as the cooling fluid. Water or oils as cooling fluid ensure that in the working temperature range of the solar cells the cooling fluid is always present in liquid form.

The cooling medium can flow in a closed circuit from a rear side of the at least one solar cell to a heat accumulator and/or to a cooling unit and/or to a heat exchanger and flow from the heat accumulator and/or from the cooling unit and/or from the heat exchanger to the rear side of the solar cell. A pump can move the cooling medium in the closed circuit so that it flows.

When solar irradiation is incident on the at least one solar cell, heat from the at least one solar cell can be stored in the phase transition material and in the process the phase transition material can be converted from a first phase into a second phase. The heat from the at least one solar cell, which heat converts the phase transition material from the first into the second phase, can be released to a heat accumulator and/or to a cooling unit and/or via a heat exchanger, as a result of which the phase transition material is converted from the second into the first phase.

The phase transition from the first phase to the second phase of the phase transition material can take place at a temperature in the range from +20 to +70 degrees Celsius and/or the cooling fluid can flow in liquid form over the entire temperature range from +20 to +70 degrees Celsius.

The advantages associated with the method are analogous to the advantages that were previously described in relation to the device.

Preferred embodiment variants of the invention with advantageous developments according to the features of the dependent claims are explained in more detail below with reference to the single FIGURE, though without being limited thereto.

### BRIEF DESCRIPTION OF THE DRAWINGS

The single FIGURE shows a sectional view of a solar module comprising solar cells and a device for cooling the solar cells by means of a cooling circuit.

### DETAILED DESCRIPTION OF INVENTION

The device 1 for cooling solar cells shown in the FIGURE has, on its top side, solar cells 2 that are electrically interconnected with one another. The interconnection 3 of the solar cells 2 is represented merely in schematic form and corresponds to the electrical interconnection which is typical for solar cells in order to build a solar module 5. The solar cells are embedded, at least with their side surfaces, in an encapsulation 4. Glass, thermosetting casting polymers or foils, inter alia, can serve as the encapsulation 4. The solar cells 2 with their interconnection 3 and the encapsulation 4 form a commercially available solar module 5.

Mounted on the rear side of the solar module 5 is a container 7 which preferably is filled completely with phase transition material 8. The solar module 5 is arranged on the container 7 in a liquid-tight manner similarly to a cover. The container 7 is part of a cooling circuit 6 which also includes a pump 10 and a cooling unit 9. Instead of or together with the cooling unit 9, a heat exchanger or a heat accumulator can also be disposed in the cooling circuit 6.

Normally the cooling circuit 6 is constructed from heat-insulated or uninsulated tubes which connect the container 7 to the cooling unit 9 by way of the pump 10 and the cooling unit 9 to the container 7. A closed circuit which is completely filled with cooling medium 8 is embodied by way of the tubes.

The cooling medium 8 consists of a cooling fluid and a phase transition material. Water, oil or an oil mixture, for example, can be used as the cooling fluid. The phase transition material is added to the cooling fluid. Paraffin or a salt, in particular sodium acetate trihydrate, for example, can be used as the phase transition material. The cooling fluid is chosen such that it will be present in liquid form in the temperature range in which the solar cells 2 operate. If the phase transition material is present in solid form, then if the phase transition material is embodied as a colloid in the cooling fluid, it is ensured that the cooling medium 8 will be present in liquid form. As a result the cooling medium 8, driven via the pump 10, can flow in the cooling circuit at all times during the operation of the solar cells 2 and convey the heat from the solar cells 2 to the cooling unit 9.

Typically the temperature range in which the solar cells 2 are operated and require to be cooled lies in the range from +20 to +70 degrees Celsius. At lower temperatures, during winter for example, no cooling of the solar cells 2 is necessary. For this reason an operating temperature of the solar cells 2 shall henceforth be understood to mean a temperature above +20 degrees Celsius.

If solar radiation acts on the solar cells 2 during the day, then they are in a state of operation and generate electricity. The solar radiation is incident on the solar cells from the front side and is absorbed in the cells. Part of the energy of the absorbed solar radiation effects a charge carrier separation between positive and negative charge carriers in a known manner and thus leads to a generation of electricity. The remainder of the absorbed solar radiation is converted into heat. Without cooling of the solar cells 2 this heat would lead to an increase in the temperature of the solar cells 2, e.g. from an ambient temperature of 20 to 30 degrees Celsius to up to 70 to 80 degrees Celsius after several hours of operation under solar irradiation.

If the solar cells 2 are cooled, a constant operating temperature can be achieved together with a high level of efficiency over the entire period of operation. In a short period of operation the cooling fluid, with its low thermal capacity, is able to absorb the waste heat of the solar cells 2 and convey it to the cooling unit 9, where the heat is e.g. released to the environment. At a high level of solar irradiation and a high ambient temperature as well as a long period of operation, especially in summer, the thermal capacity of the cooling fluid is not sufficient to absorb the entire quantity of heat accumulating at the solar cells 2.

Under these conditions the phase transition material brings about an increase in the thermal capacity of the cooling medium 8. At least over wide temperature ranges the cooling medium 8 with phase transition material can absorb the quantity of heat accumulating at the solar cells 2 in addition to the quantity of heat absorbed by the cooling fluid. At times of higher levels of solar irradiation the solar cells 2 can consequently be operated over a longer period of time at a lower temperature and at a high level of efficiency. By increasing the thermal capacity of the cooling medium 8 with the aid of the phase transition material it is possible, at the same flow velocity of the cooling medium 8, to remove a greater quantity of heat from the solar cells 2 by comparison with a cooling medium 8 without phase transition material.

As a result of the waste heat of the solar cells 2 being absorbed by way of the cooling medium 8 the phase transition material is heated. A phase transition takes place in the phase transition material at a specific temperature. During said phase transition a large quantity of heat is converted or, as the case may be, absorbed in order to change the phase and therefore the structure of the phase transition material. This results in a lot of heat being stored by the phase transition material without leading to a significant increase in temperature. The solar cells 2 can therefore give off a large quantity of heat with practically no increase in the temperature of the cooling medium 8 taking place. A further increase in temperature takes place only after a complete phase conversion of the phase transition material. A high heat mass flow is thereby achieved at a low volume flow rate of the cooling medium 8. A large amount of heat can be conveyed from the solar cells 2 to the cooling unit 9 by way of the cooling circuit 6.

At the cooling unit 9 the phase transition material can release its stored quantity of heat to the environment by way of the cooling medium 8, a phase reconversion of the phase transition material generally taking place in the process. Use is made here of the temperature difference between the temperature of the solar cells 2 under solar irradiation and the temperature e.g. of the ambient air of the cooling unit 9. At a lower temperature of the cooling unit 9 compared with the temperature of the solar cells 2 the cooling medium 8 is cooled down. The cooling fluid releases its small quantity of absorbed heat to the environment by way of the cooling unit 9. At an ambient temperature lying below the temperature of the phase conversion of the phase transition material, a phase conversion of the phase transition material takes place. In the process the quantity of heat that was stored close to the solar cells 2 during the phase conversion is released again.

The cooled cooling medium 8 with the reconverted phase transition material is then conveyed back to the solar module 5 again via the cooling circuit 6. The circuit is thus closed and the cooling medium 8 can absorb heat from the solar cells 2 once more.

The optimal phase transition material must be chosen according to the accumulating quantity of heat and the therewith associated increase in temperature of the solar cells 2 during operation under solar irradiation and according to the ambient temperature of the cooling unit 9 as well as the capacity of the pump 10. The temperature of the phase conversion of the phase transition material should lie above the highest occurring ambient temperature of the cooling unit 9, and furthermore it should be as low as possible so that the solar cells 2 are cooled down during operation to a temperature close to the ambient temperature. Examples of accordingly suitable phase transition materials include paraffins, salt hydrates such as e.g. sodium sulfate decahydrate or potassium aluminum sulfate dodecahydrate and sodium acetate trihydrate.

1.-16. (canceled)

17. A device for cooling at least one solar cell, comprising:
a cooling medium, wherein the cooling medium is in direct or indirect thermal contact with the at least one solar cell; and
an external cooling unit,
wherein the cooling medium at least includes a phase transition material.

18. The device as claimed in claim 17, wherein the cooling medium comprises a cooling fluid and the phase transition material.

19. The device as claimed in claim 17, wherein the phase transition material comprises paraffin or salt.

20. The device as claimed in claim 17, wherein the phase transition material consists of paraffin or salt.

21. The device as claimed in claim 19, wherein the phase transition material comprises sodium acetate trihydrate.

22. The device as claimed in claim 20, wherein the phase transition material consists of sodium acetate trihydrate.

23. The device as claimed in claim 17, wherein the phase transition material has a phase change temperature in a range between +20 and +70 degrees Celsius.

24. The device as claimed in claim 17, wherein the phase transition material has a specific thermal capacity of greater than two kilojoules per kilogram per Kelvin.

25. The device as claimed in claim 17, wherein the phase transition material is incorporated in a closed circuit, wherein, via the cooling medium, a rear side of the at least one solar cell is thermally coupled by the closed circuit to a heat accumulator and/or to the cooling unit and/or to a heat exchanger.

26. The device as claimed in claim 25, wherein a pump is arranged in the closed circuit such that
the cooling medium flows from the rear side of the at least one solar cell to the heat accumulator and/or to the cooling unit and/or to the heat exchanger, and
the cooling medium flows back from the heat accumulator and/or from the cooling unit and/or from the heat exchanger to the rear side of the solar cell in the closed circuit.

27. A method for cooling solar cells, comprising:
providing a cooling medium;
contacting thermally at least one solar cell directly or indirectly with the cooling medium,
wherein the cooling medium comprises a phase transition material.

28. The method as claimed in claim 27, further comprising:
providing a mixture of the phase transition material and a cooling fluid as the cooling medium,
wherein the cooling fluid flows in liquid form during a cooling of the at least one solar cell, and
wherein the phase transition material is conveyed in the cooling fluid in all phases of the phase transition material, in particular in a liquid and a solid phase of the phase transition material.

29. The method as claimed in claim 28, wherein the phase transition material comprises paraffin or a salt, wherein the paraffin or salt is present in a solid phase as a colloid in the cooling fluid.

30. The method as claimed in claim 29, wherein the phase transition material comprises sodium acetate trihydrate.

31. The method as claimed in claim 28, wherein water or an oil or an oil mixture is provided as the cooling fluid.

32. The method as claimed in claim 27, further comprising:
providing a heat accumulator and/or a cooling unit and/or a heat exchanger,
wherein the cooling medium flows in a closed circuit from a rear side of the at least one solar cell to the heat accumulator and/or to the cooling unit and/or to the heat exchanger and flows from the heat accumulator and/or from the cooling unit and/or from the heat exchanger to the rear side of the solar cell.

33. The method as claimed in claim 32, wherein a pump moves the cooling medium in the closed circuit.

34. The method as claimed in claim 27, further comprising:
storing heat from the at least one solar cell in the phase transition material when solar irradiation is incident on the at least one solar cell, and
converting the phase transition material from a first phase into a second phase.

35. The method as claimed in claim 34, further comprising:
releasing the heat of the phase transition material to a heat accumulator and/or a cooling unit and/or a heat exchanger, and
reconverting the phase transition material from the second phase to the first phase.

36. The method as claimed in claim 34, wherein a phase transition from the first phase to the second phase of the phase transition material takes place at a temperature in a range from +20 to +70 degrees Celsius and/or the cooling fluid flows in liquid form over the entire temperature range from +20 to +70 degrees Celsius.
